(19) United States
(12) Patent Application Publication
(10) Pub. No.: US 2009/0009280 A1
(43) Pub. Date: Jan. 8, 2009

(54) Magnetic core for current sensor having high magnetic saturation

(75) Inventor: Masato Ishihara, Anjo-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/078,366

(22) Filed: Mar. 31, 2008

(30) Foreign Application Priority Data
Jul. 5, 2007 (JP) 2007-177382

(51) Int. Cl. H01F 27/24; G01R 15/20

(52) U.S. Cl. 336/234; 324/117 H

(57) ABSTRACT

A magnetic core according to the present invention is used in a current sensor for detecting amount of current flowing through a conductor by a Hall element. The magnetic core is made of a resin material, in which a granular magnetic material is dispersed, and is shaped to form a circular magnetic flux passage therein by injection molding. The magnetic core is formed by laminating plural layers in an inside to outside direction of the magnetic core, and a magnetic material content is made higher in the outer layers than in the inner layers. In this manner, uniformity of the magnetic flux density in the core is improved. Alternatively, the magnetic core is made by laminating plural layers having respective magnetic material content ratios in its thickness direction to adjust magnetic saturation to a desired level. A measurable range of electric current is widened by suppressing magnetic saturation in the magnetic core without increasing its size.

### CROSS-REFERENCE TO RELATED APPLICATION

This application is based upon and claims benefit of priority of Japanese Patent Application No. 2007-177382 filed on Jul. 5, 2007, the content of which is incorporated herein by reference.

### BACKGROUND OF THE INVENTION

1. Field of the Invention

The present invention relates to a magnetic core for use in a current sensor that detects an amount of current by Hall element based on magnetic flux generated in the magnetic core by electric current.

2. Description of Related Art

An example of a current sensor that uses a Hall element is disclosed in JP-A-2002-296305. A magnetic core is formed in a circular shape having a gap by laminating three magnetic core plates made of a magnetic material. A through-hole is made in the center of the magnetic core, and a Hall element for detecting an amount of magnetic flux in the magnetic core is disposed in the gap.

Following problems, however, are involved in the conventional current sensor disclosed in JP-A-2002-296305. A size of the magnetic core is relatively large in an entire current sensor, and therefore it has been difficult to make the current sensor compact. In particular, for detecting a large amount of current, it has been necessary to increase the number of laminated core plates to increase a cross-sectional area of the magnetic core.

### SUMMARY OF THE INVENTION

The present invention has been made in view of the above-mentioned problem, and an object of the present invention is to provide an improved magnetic core for use in a current sensor that is able to detect a large amount of current while suppressing the size of the magnetic core.

The magnetic core of the present invention is used in a current sensor for detecting an amount of current by a Hall element. The magnetic core is shaped to form a circular magnetic flux passage having a gap in which the Hall element is disposed. The magnetic core is made of a resin material in which a granular magnetic material such as permalloy is dispersed. A content ratio of the granular magnetic material in a total weight is made about 50%, for example. The magnetic core is formed by injection molding.

The magnetic core forming the circular magnetic flux passage has a through-hole at its center portion. A conductor through which electric current to be measured flows is disposed in the through-hole. Magnetic flux is generated in the magnetic core by the electric current. An amount of the magnetic flux in the magnetic core is measured by the Hall element, and thereby an amount of current is detected.

The magnetic core is formed by laminating magnetic core layers (e.g., two layers) in a direction from an inside to an outside of the magnetic core. The content ratio of the magnetic material is made higher in the outer layer than in the inner layer. In this manner, a flux density in the magnetic core is made uniform because the density of the magnetic flux becomes higher in the inside portion if the content ratio of the magnetic material is uniform. Alternatively, the magnetic core is formed by laminating plural magnetic core layers, each having s different magnetic material content ratio, in the thickness direction. In this manner, a degree of magnetic saturation in the magnetic core is easily adjusted to a desired level.

By dispersing the granular magnetic material in the resin material, magnetic saturation in the magnetic core is suppressed because dispersion of the granular magnetic material has the same effect as the magnetic core is divided into small sections. A large amount of current can be measured by avoiding magnetic saturation in the magnetic core without increasing the core size. A degree of the magnetic saturation can be adjusted by selecting a grain size of the magnetic material or its content ratio in the resin material.

The magnetic core may be subjected to weather-resistive surface treatment after it is molded to improve its weather resistance. Glass fibers may be added to the resin material to improve a mechanical strength of the magnetic core. The molding process of the magnetic core may be performed under a magnetic field to direct grain crystals in the same direction.

According to the present invention, a measurable range of the current sensor is widened by avoiding the magnetic saturation in the magnetic core without increasing a size of the magnetic core. Other objects and features of the present invention will become more readily apparent from a better understanding of the preferred embodiments described below with reference to the following drawings.

### BRIEF DESCRIPTION OF THE DRAWINGS

FIG. 1A is a perspective view showing a current sensor in which a magnetic core as a first embodiment of the present invention is used;

FIG. 1B is a partially enlarged view showing granular soft magnetic material contained in a resin material forming the magnetic core;

FIG. 2A is a schematic drawing showing large grains of the soft magnetic material contained in the resin material;

FIG. 2B is a schematic drawing showing small grains of the soft magnetic material contained in the resin material;

FIG. 3 is a plan view showing a magnetic core as a second embodiment of the present invention;

FIG. 4 is a side view showing a magnetic core as a third embodiment of the present invention;

FIG. 5 is a plan view showing a magnetic core as a fourth embodiment of the present invention; and

FIG. 6 is a plan view showing a magnetic core as a fifth embodiment of the present invention.

### DETAILED DESCRIPTION OF THE PREFERRED EMBODIMENTS

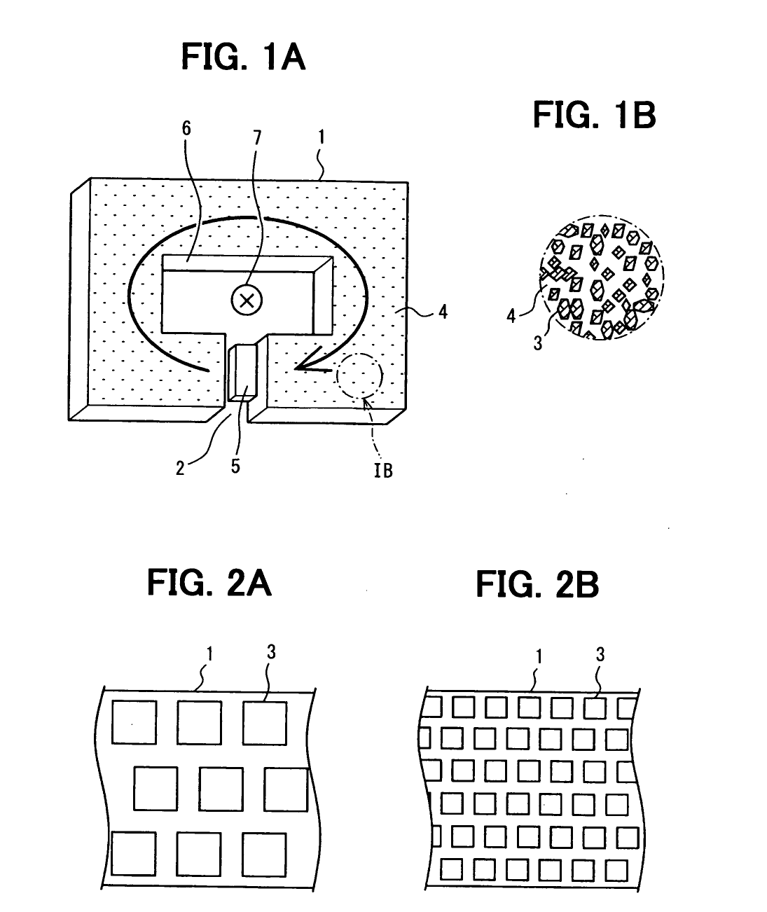

A first embodiment of the present invention will be described with reference to FIGS. 1A-2B. As shown in FIG. 1A, the magnetic core 1 is formed in a rectangular shape having a gap 2. The magnetic core 1 is formed by injection molding. The material forming the magnetic core 1 is a resin material that contains granular soft magnetic material such as permalloy. As shown in FIG. 1B, the granular soft magnetic material 3 is dispersed in the resin material 4. If a higher mechanical strength of the magnetic core 1 is required, glass fibers may be added to the resin material.

A conductor 7 is positioned in a through-hole 6 formed in the magnetic core 1. Magnetic flux is generated in the magnetic core 1 according to an amount of electric current flowing through the conductor 7. The amount of magnetic flux is measured by a Hall element 5 fixedly disposed in the gap 2. Thus, the amount of current flowing through the conductor 7 is detected by the Hall element 5. Current sensors other than the Hall element 5 may be used for detecting the current.

The magnetic core 1 made of the resin material containing the granular soft magnetic material is suitable to detect a large amount of current because magnetic saturation in the magnetic core 1 is avoided. The magnetic saturation can be avoided also by dividing a laminated magnetic core into plural portions as shown in JP-A-2006-71456. By reducing magnetic flux density in a magnetic core, the magnetic saturation in the magnetic core can be avoided. If the magnetic saturation does not occur, a larger amount of current can be measured.

The same effect that is obtained by dividing the magnetic core into plural portions is attained by dispersing granular soft magnetic material in the resin material. The amount of the dispersed granular soft magnetic material in a total weight of the material forming the magnetic core 1 is made about 50%. In other words, a ratio of the resin to the magnetic material is about 50:50. An average grain size of the granular soft magnetic material is about 10 μm, for example.

FIGS. 2A and 2B schematically show grains of soft magnetic material 3 dispersed in the resin material 4. FIG. 2A shows larger grains dispersed in the resin while FIG. 2B shows smaller grains. If the same ratio (relative to the resin) of the granular soft magnetic material is dispersed, the magnetic saturation is avoided more effectively by making the grain size smaller because the smaller grains function as if a magnetic core were divided into a higher number of small portions. In other words, the magnetic saturation in the magnetic core 1 can be adjusted by adjusting the grain size of the soft magnetic material dispersed in the resin material. By suppressing the magnetic saturation in the magnetic core 1, the amount of current can be detected in a wider range, from a small amount to a large amount without making the size of the magnetic core larger. In this manner, the current sensor can be made compact.

A measurable amount of current can be further increased by making the content ratio of the granular soft magnetic material dispersed in the resin smaller. In other words, a measurable range of current can be changed by changing the content ratio of the magnetic material without changing the size of the magnetic core and other components.

In a process of mixing the granular soft magnetic material 3 with the resin 4, non-magnetic material such as alumina may be mixed with the resin 4. In this case, it is preferable to maintain a ratio of the resin 4 to other materials (e.g., the magnetic material plus the non-magnetic material) unchanged to keep the molding conditions unchanged. The measurable current range is changed by changing the amount of non-magnetic material added to the magnetic material while keeping the content ratio of the resin constant. In the case where the glass fibers are added to the resin to increase the mechanical strength of the magnetic core 1, it is preferable to add the glass fibers, keeping the content ratio of the resin plus glass fibers to other materials unchanged.

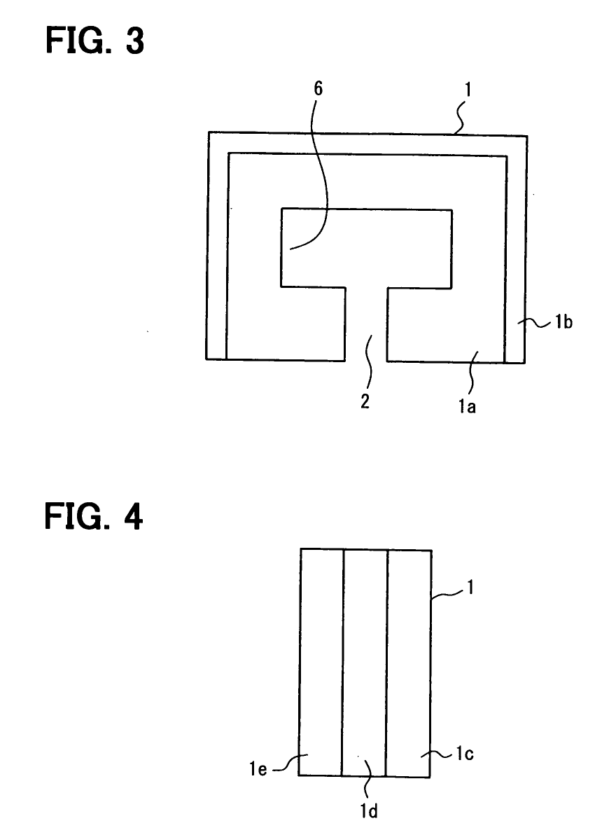

A second embodiment of the present invention is shown in FIG. 3. In this embodiment, the magnetic core 1 is formed by laminating an inner magnetic core layer 1a and an outer magnetic core layer 1b in a direction from the through-hole 6 to the outside of the magnetic core 1. Other structures are the same as those of the first embodiment. The content ratio of the granular soft magnetic material 3 relative to the resin material 4 is made higher in the outer layer 1b than in the inner layer 1a. Since the magnetic flux flows more easily through the inner portion of the magnetic core 1, the magnetic flux density can be made uniform by forming the magnetic core 1 as above. The number of laminated layers is not limited to two, but more than two layers may be laminated. In this case, the content ratio of the magnetic material is made higher as the layers go outside.

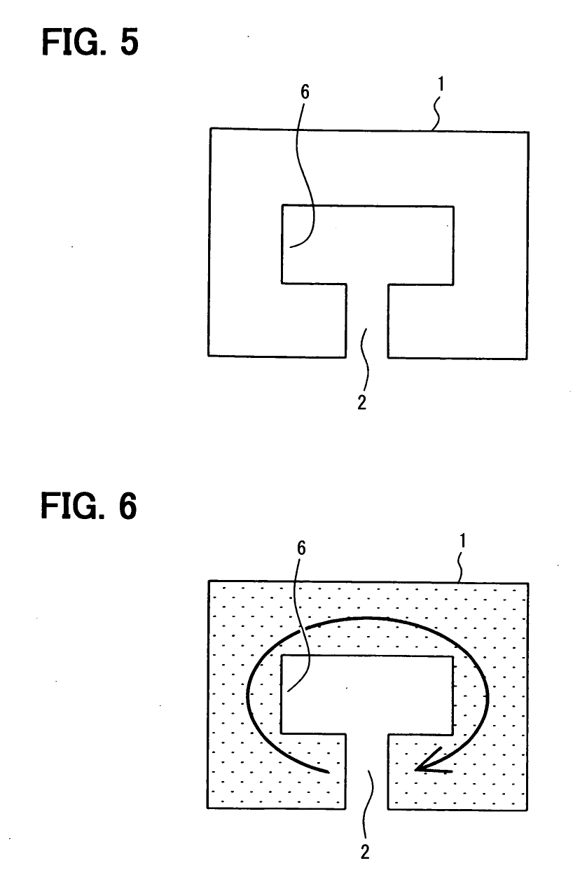

FIG. 4 shows a side view of a third embodiment of the present invention. A plan view is the same as FIG. 1A showing the first embodiment. In this embodiment, the magnetic core 1 is composed of three layers, a lower layer 1e, a middle layer 1d and an upper layer 1c. The content ratio of the soft magnetic material to the resin material is adjusted by layer by layer. Other structures and functions are the same as those of the first embodiment.

FIG. 5 shows a fourth embodiment of the present invention. In this embodiment, the magnetic core 1 is subjected to weather-resistive surface treatment after it is molded. Accordingly, the surface of the magnetic core 1 is covered with a weather-resistive layer. Other structures and functions are the same as those of the foregoing embodiments.

FIG. 6 shows a fifth embodiment of the present invention. In this embodiment, the magnetic core 1 is molded under a magnetic filed imposed thereon. By imposing the magnetic field in the molding process, crystal directions of the grains of the soft magnetic material can be made uniform thereby to improve core characteristics.

The present invention is not limited to the embodiments described above, but it may be variously modified. For example, though the magnetic core 1 is formed in a rectangular shape in the foregoing embodiments, it may be formed in various shapes, such as square, round or oval shapes. The corners of the rectangular-shaped magnetic core 1 shown above may be made round. While the present invention has been shown and described with reference to the foregoing preferred embodiments, it will be apparent to those skilled in the art that changes in form and detail may be made therein without departing from the scope of the invention as defined in the appended claims.

What is claimed is:

1. A magnetic core for use in a current sensor that detects an amount of electric current by a Hall element based on magnetic flux generated in the magnetic core by electric current, wherein:
the magnetic core is made of a resin material by injection molding, the resin material including granular soft magnetic material dispersed in the resin material;
the magnetic core is shaped to form a circular magnetic flux passage having a gap for disposing the Hall element therein by laminating plural magnetic core layers in a direction from an inner portion to an outer portion of the magnetic core; and
a content ratio of the granular soft magnetic material in the resin material is made higher in the magnetic core layers positioned outside than in the magnetic core layers positioned inside.

2. A magnetic core for use in a current sensor that detects an amount of electric current by a Hall element based on magnetic flux generated in the magnetic core by electric current, wherein:
the magnetic core is made of a resin material by injection molding, the resin material including granular soft magnetic material dispersed in the resin material; and
the magnetic core is shaped to form a circular magnetic flux passage having a gap for disposing the Hall element therein by laminating plural magnetic core layers in a thickness direction that is perpendicular to the circular magnetic flux passage; and
a content ratio of the granular soft magnetic material in the resin material is made different layer by layer.

3. The magnetic core as in claim 1, wherein the magnetic core is subjected to a weather-resistive surface treatment.

4. The magnetic core as in claim 2, wherein the magnetic core is subjected to a weather-resistive surface treatment.

5. The magnetic core as in claim 1, wherein the magnetic core is molded while a magnetic field is being imposed thereon.

6. The magnetic core as in claim 2, wherein the magnetic core is molded while a magnetic field is being imposed thereon.

7. The magnetic core as in claim 1, wherein the resin material including the granular soft magnetic material dispersed therein further contains glass fibers mixed therewith.

8. The magnetic core as in claim 2, wherein the resin material including the granular soft magnetic material dispersed therein further contains glass fibers mixed therewith.

9. The magnetic core as in claim 1, wherein the magnetic core forming the circular magnetic flux passage is substantially in a rectangular shape.

10. The magnetic core as in claim 2, wherein the magnetic core forming the circular magnetic flux passage is substantially in a rectangular shape.
